(19) United States
(12) Patent Application Publication
(10) Pub. No.: US 2025/0056872 A1
(43) Pub. Date: Feb. 13, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: WAN-LIN TSAI, HSINCHU CITY (TW); KAI-QIANG WEN, HSINCHU (TW); I-SHENG CHEN, TAIPEI CITY (TW); YI-JING LI, HSINCHU CITY (TW); SHIH-CHUN FU, HSINCHU CITY (TW); CLEMENT HSINGJEN WANN, CARMEL, NY (US)

(21) Appl. No.: 18/448,187

(22) Filed: Aug. 11, 2023

(51) Int. Cl. H01L 27/06; H01L 29/40; H01L 29/66; H01L 29/8605

(52) U.S. Cl. CPC H01L 27/0629; H01L 29/404; H01L 29/66166; H01L 29/8605

(57) ABSTRACT

The present disclosure provides a semiconductor device. The semiconductor device includes a substrate, an active region on the substrate, and a gate structure, a source conductor, and a drain conductor disposed on the active region. The semiconductor device further comprises a first type doped region of the active region below the gate structure and a second type doped region of the active region adjacent to the first type doped region, and the first type doped region is different from the second type doped region. The second type doped region is configured to function as a resistor.

### BACKGROUND

With the rapid growth of the electronics industry, the development of integrated circuits (ICs) consistently demands improvements in performance and miniaturization. Technological advances in IC materials and design have produced generations of ICs in which each generation has smaller and more complex circuits than the previous generation. A plurality of transistors and passive components (such as resistors, capacitors, and inductors) are commonly used as fundamental construction building blocks for ICs. Since the area occupied by each component is usually considered as a cost in the semiconductor manufacturing process, the dimensions and areas of the passive components are of prime consideration in the design of the IC layout. A semiconductor device free from the constraints imposed by dimensions of passive components is therefore called for.

### BRIEF DESCRIPTION OF THE DRAWINGS

Aspects of the present disclosure are best understood from the following detailed description when read with the accompanying figures. It is emphasized that, in accordance with standard practice in the industry, various features are not drawn to scale. In fact, the dimensions of the various features may be arbitrarily increased or reduced for clarity of discussion.

FIG. 1 is a diagram illustrating a concept of area reduction in IC layout design, in accordance with some embodiments.

FIG. 2 illustrates a circuit that can benefit from the proposed layout design, in accordance with some embodiments.

FIG. 3 is a diagram illustrating a concept of area reduction in IC layout design, in accordance with some embodiments.

FIG. 4 illustrates a semiconductor device including a transistor and an embedded resistor, in accordance with some embodiments.

FIG. 5 illustrates a layout of a semiconductor device including two transistors and two embedded resistors, in accordance with some embodiments.

FIG. 6 is a cross section along the dashed line B-B′ of FIG. 5, in accordance with some embodiments.

FIG. 7 illustrates a layout of a semiconductor device including transistors and two embedded resistors, in accordance with some embodiments.

FIG. 8 is a flowchart of a method of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower.” “above.” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° or at other orientations) and the spatially relative descriptors used herein may likewise be interpreted accordingly.

Embodiments, or examples, illustrated in the drawings are disclosed as follows using specific language. It will nevertheless be understood that the embodiments and examples are not intended to be limiting. Any alterations or modifications in the disclosed embodiments, and any further applications of the principles disclosed in this document are contemplated as would normally occur to one of ordinary skill in the pertinent art.

Further, it is understood that several processing steps and/or features of a device may be only briefly described. Also, additional processing steps and/or features can be added, and certain of the following processing steps and/or features can be removed or changed while still implementing the claims. Thus, it is understood that the following descriptions represent examples only, and are not intended to suggest that one or more steps or features are required.

In addition, the present disclosure may repeat reference numerals and/or letters in the various examples. This repetition is for the purpose of simplicity and clarity and does not in itself dictate a relationship between the various embodiments and/or configurations discussed.

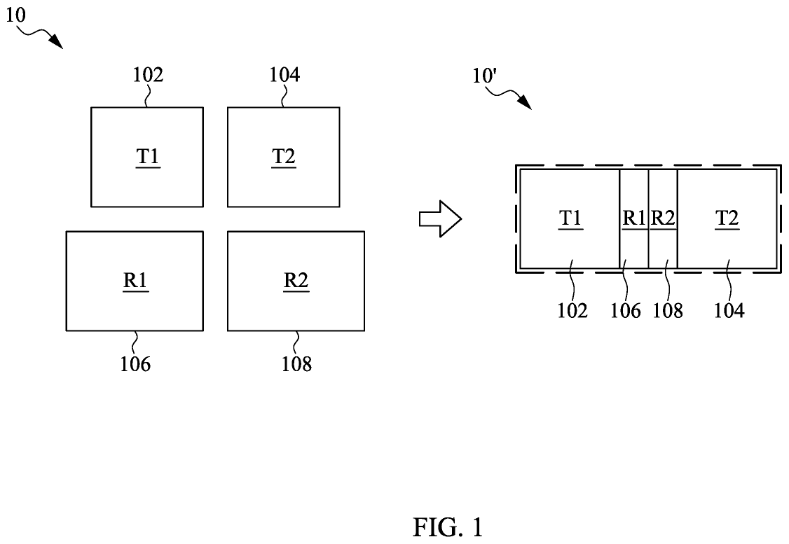

FIG. 1 is a diagram illustrating a concept of area reduction in IC layout design, in accordance with some embodiments. FIG. 1 shows two IC layouts 10 and 10′. In some embodiments, the IC layout 10 includes four regions 102, 104, 106, and 108. Two active components, such as transistors T1 and T2, can be located within the regions 102 and 104. Two passive components, such as resistors R1 and R2, can be located within the regions 106 and 108. The IC layout 10′ includes four regions 102, 104, 106, and 108. A hybrid component including an active component (e.g., transistor T1) and a passive component (e.g., resistor R1) can be located at the regions 102 and 106. Similarly, another hybrid component including an active component (e.g., transistor T2) and a passive component (e.g., resistor R2) can be located within at the regions 104 and 108.

In some embodiments, the resistor R1 may be embedded in a portion of the transistor T1 and the resistor R2 may be embedded in a portion of the transistor T2. The IC layout 10′ includes the same number of components (i.e., two transistors and two resistors) as IC layout 10, but can occupy less overall area on the semiconductor wafer. With the hybrid components introduced in the IC layout 10′, an area reduction can be achieved. In some embodiments, the IC layout 10′ may be one cell unit. The IC layout 10′ integrated a pair of resistors and a pair of transistors into one cell unit and no extra area is required.

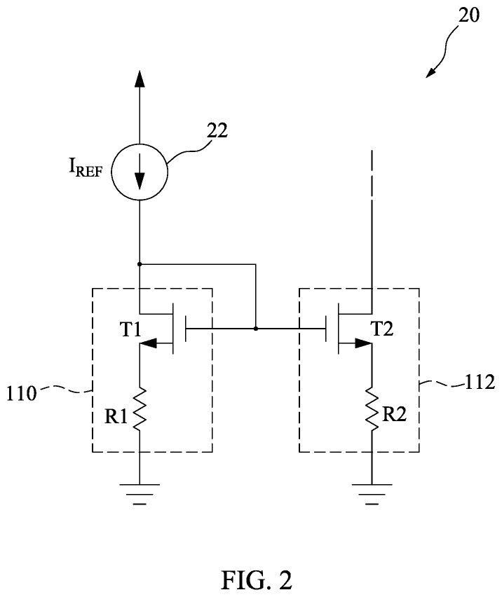

FIG. 2 illustrates a circuit that can benefit from the proposed layout design, in accordance with some embodiments. FIG. 2 shows a current mirror circuit 20. The current mirror circuit 20 includes transistors T1 and T2, resistors R1 and R2, and a current source 22. The resistor R1 is electrically connected to the source terminal of the transistor T1. The resistor R2 is electrically connected to the source terminal of the transistor T2. The gate terminal of the transistor T1 is electrically connected to the drain terminal of the transistor T1. The current source 22 is electrically connected to the drain terminal of the transistor T1. The gate terminal of the transistor T1 is electrically connected to the gate terminal of the transistor T2.

The current mirror circuit 20 can be utilized in a current-controlled oscillator (ICO), in which the resistors R1 and R2 can be referred to as a “source degeneration” mechanism that can reduce the noise of the ICO.

The resistors R1 and R2 can be selected to be the same (for example, resistor Rs) in the “source degeneration” mechanism for ICO, and can improve the noise current of the ICO by a factor “1+gm*Rs.” The parameter “gm” represents the transconductance of the transistors T1 and T2, and the Rs is selected to be greater than 1/gm. In traditional layout design for the current mirror circuit 20, resistors R1 and R2 usually occupy regions different from those for transistors T1 and T2 (for example, see the IC layout 10 of FIG. 1). The IC layout 10 can be considered less area-efficient. On the contrary, if the resistor R1 and the transistor T1 can be located within the same region 110, and the resistor R2 and the transistor T2 can be located within the same region 112, as those arranged in the IC layout 10′ of FIG. 1, the area usage of the ICO on a semiconductor wafer can be reduced. The transistor T1 and the resistor R1 within the region 110 can be implemented by any one of the layout structures as shown in accordance with some embodiments of the present disclosure. The transistor T2 and the resistor R2 within the region 112 can be implemented by any one of the layout structures shown in accordance with some embodiments of the present disclosure.

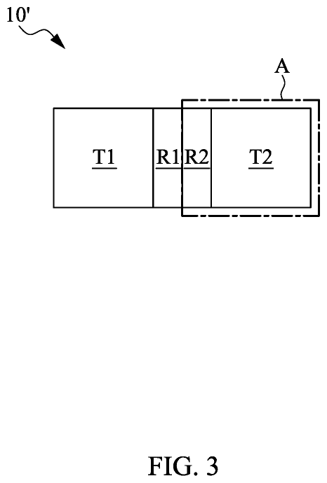

FIG. 3 is a diagram illustrating a concept of area reduction in IC layout design, in accordance with some embodiments. FIG. 3 shows one IC layout 10′. In some embodiments, the IC layout 10′ includes two transistors T1 and T2 and two resistors R1 and R2. The resistor R1 is located adjacent to the transistor T1. The resistor R2 is located adjacent to the transistor T2. The resistor R2 is located adjacent to the resistor R1. One hybrid component includes an active component (e.g., transistor T2) and a passive component (e.g., resistor R2). The area “A” of FIG. 3 includes one hybrid component.

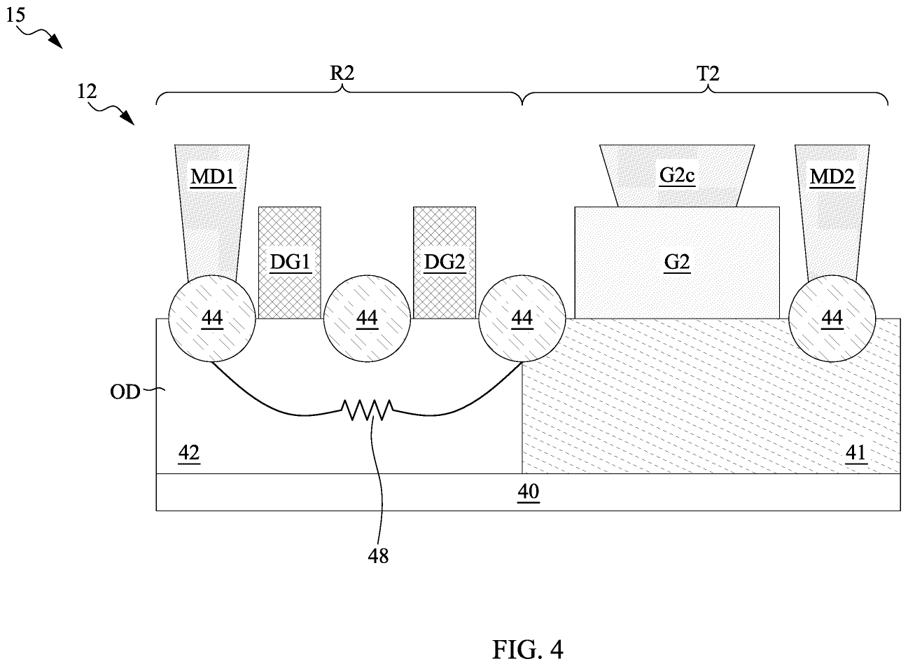

FIG. 4 is a semiconductor device including a transistor and an embedded resistor, in accordance with some embodiments. The semiconductor device 15 as shown in FIG. 4 pertains to a semiconductor device including a transistor T2 and a resistor R2. Alternatively, the semiconductor device 15 can also be deemed as a transistor having an embedded resistor.

In some embodiments, the semiconductor device 15 can correspond to a top view perspective of the IC layout 10′ within the area “A” including a transistor T2 and a resistor R2. The semiconductor device 15 includes a substrate 40, an active region OD, a gate structure G2, a source conductor MD1, a drain conductor MD2, two dummy gate structures DG1 and DG2, and epitaxial contacts 44. In some embodiments, the active region OD includes a first type doped region 41 and a second type doped region 42. The active region OD is disposed on the substrate 40.

In some embodiments, the semiconductor device 15 comprises the gate structure G2, the source conductor MD1, and the drain conductor MD2 disposed on the active region OD. In some embodiments, the semiconductor device 15 comprises a first type doped region 41 of the active region OD below the gate structure G2. The semiconductor device 15 comprises a second type doped region 42 of the active region OD adjacent to the first type doped region. The first type doped region 41 is different from the second type doped region 42. In some embodiments, the first type doped region 41 is a p-type doped region and the second type doped region 42 is a n-type doped region. In some embodiments, the first type doped region 41 is a n-type doped region and the second type doped region 42 is a p-type doped region. In some embodiments, when the semiconductor device 15 is turned on or operated, the second type doped region 42 is configured to function as a resistor 48. The path within the second type doped region 42 through which the current passes corresponds to the resistor 48. The source conductor MD1 is disposed on the epitaxial contacts 44, and the drain conductor MD2 is disposed on the epitaxial contacts 44.

In some embodiments, a first dummy gate structure DG1 is disposed on the second type doped region 42. A second dummy gate structure DG2 is disposed on the second type doped region 42. The second dummy gate structure DG2 is disposed between the first dummy gate structure DG1 and the source conductor MD1. In some embodiments, one of the epitaxial contacts 44 is disposed between the first dummy gate structure DG1 and the gate structure G2. In some embodiments, one of the epitaxial contacts 44 is disposed adjacent to an interface between a boundary of the first type doped region 41 and a boundary of the second type doped region 42. One of the epitaxial contacts 44 is disposed between the first dummy gate structure DG1 and the second dummy gate structure DG2. A gate contact G2c is formed on the gate structure G2. In some embodiments, the number of the dummy gate structures can be increased. The newly added dummy gate structure can be disposed between the first dummy gate structure DG1 and the source conductor MD1. The number of the dummy gate structures DG1 and DG2 of the semiconductor device 15 is 2. In some embodiments, the number of the dummy gate structures may be more than 2 (e.g., the number of the dummy gate structures may be 3, 4, 5 . . . , etc.). The resistance value of the resistor 48 increases with the increased number of total dummy gate structures. If the number of the total dummy gate structures is increased, the current path of the resistor 48 is correspondingly increased. Compared to the first type doped region 41, the second type doped region 42 has a higher resistance value when the semiconductor device 15 is turned on or enabled.

The present disclosure provides a semiconductor device structure achieving a low noise performance by using a simple layout design which can be compatible with the process for manufacturing semiconductor devices. The device of the present disclosure consists of a pair of resistors and transistors into an unit of the semiconductor device. The present disclosure adopts a simple layout design for multi-finger structures. The properties of the resistors R1 and R2 and transistors T1 and T2 can be controlled independently. In some embodiments, the resistance value of the n-type well resistor may be controlled by the number/size of dummy gate structures on the resistor R1/R2.

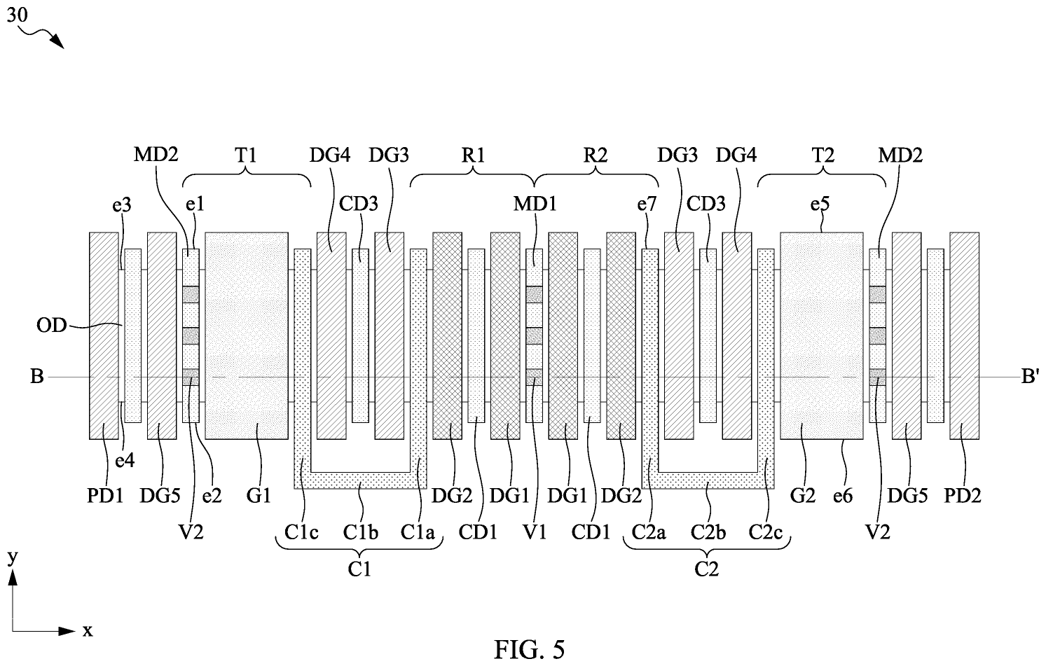

FIG. 5 is a layout of a semiconductor device including two transistors and two embedded resistors, in accordance with some embodiments. The layout 30 shown in FIG. 5 pertains to a semiconductor device including two transistors and two resistors. The layout 30 can correspond to a top view perspective of a semiconductor device including two transistors and two resistors. The layout 30 includes an active region OD, a gate structure G1, a gate structure G2, a source conductor MD1, two drain conductors MD2, dummy gate structures DG1, DG2, DG3, DG3, DG4, and DG5, conductors CD1 and CD3, and poly structures PD1 and PD2. The active region OD can also be referred to as oxide diffusion region OD. The poly structures PD1 and PD2 can be referred to as poly structures on OD edges, or simply “PODE.”

The source conductor MD1 and the drain conductor MD2 are disposed on opposite sides of the gate structure G1. In some embodiments, a conductive via V1 is disposed on the source conductor MD1 and a conductive via V2 is disposed on the drain conductor MD2. The source conductor MD1 and the drain conductor MD2 are disposed on opposite sides of the gate structure G2. The length of the source conductor MD1 is shorter than the length of the gate structure G1 from a top view. The length of the source conductor MD1 is shorter than the length of the gate structure G2 from a top view. The length of the drain conductor MD2 is shorter than the length of the gate structure G1 from a top view. The length of the drain conductor MD2 is shorter than the length of the gate structure G2 from a top view. Since the lengths of the source conductor MD1 and the drain conductor MD2 are the same, the semiconductor device manufactured in accordance with the layout 30 can be referred to as a device with balanced source/drain conductors.

The drain conductor MD2 includes edges e1 and e2, the active region OD includes edges e3 and e4, and the gate conductor G2 includes edges e5 and e6. The edges e3 and e4 of the active region OD can also be referred to as boundaries e3 and e4. The edge e1 of the drain conductor MD2 is misaligned with the edge e3 of the active region OD, and edge e2 of the drain conductor MD2 is misaligned with the edge e4 of the active region OD. The edges e3 and c4 of the active region OD can be located between edges e1 and e2 of the drain conductor MD2. The edges e3 and e4 of the active region OD can be located between edges e5 and e6 of the gate conductor G2.

The edge e5 of the gate conductor G2 is misaligned with the edge e3 of the active region OD, and edge e6 of the gate conductor G2 is misaligned with the edge e4 of the active region OD. The edges e1 and e2 of the drain conductor MD2 are both outside the area (e.g., defined by edges e3 and e4) of the active region OD. The edge e1 of the drain conductor MD2 is misaligned with the edge e5 of the gate conductor G2, and edge e2 of the drain conductor MD2 is misaligned with the edge e6 of the gate conductor G2.

In some embodiments, the drain conductor MD2 are disposed over a single active region OD. In some embodiments, the drain conductor MD2 will not extend to another active region (not shown) adjacent to the active region OD depicted in FIG. 5.

The source conductor MD1, the gate structures G1 and G2, and the drain conductors MD2 can constitute a transistor T1/T2 having resistor regions electrically connected to the source of the transistor T1/T2. In some embodiments, the length of the source conductor MD1 can range from 0.1 times to 0.9 times that of the drain conductor MD2 from a top view. In some embodiments, the length of the source conductor MD1 can range from 0.1 times to 0.9 times that of the gate structure G1 from a top view.

In some embodiments, the length of the source conductor MD1 (i.e., along the y-axis) can range from 3 nm to 5 μm. In some embodiments, the length of the drain conductor MD2 (i.e., along the y-axis) can range from 3 nm to 5 μm. In some embodiments, the width of the gate structure G1 (i.e., along the x-axis) can range from 3 nm to 10 μm. The poly structures PD1 and PD2 can be useful in process control during manufacturing. The dummy gate structures DG1 and DG2 are optional (i.e., not mandatory in the layout 30) and can be useful in reducing layout dependence effects. The number of the dummy gate structures can be increased or decreased depending on user requirements.

In some embodiments, a third dummy gate structure DG3 is disposed on the second type doped region 42. In some embodiments, a fourth dummy gate structure DG4 is disposed on the first type doped region 41. In some embodiments, a connection element C2 is disposed on the active region OD. The connection element C2 comprises a first portion C2a, a second portion C2b, and a third portion C2c. The first portion C2a is disposed between the second dummy gate structure DG2 and the third dummy gate structure DG3. The first portion C2a, the second portion C2b, and the third portion C2c are integrated in one piece. The connection element C2 can direct the current via the first portion C2a to the third portion C2c. The connection element C2 can bypass the path within the second type doped region 42 below the third dummy gate structure DG3 by directing the current. The connection element C2 can bypass the path within the first type doped region 41 below the fourth dummy gate structure DG4 by directing the current. The resistance value of the semiconductor device 15 can be reduced by directing the current through the connection element C2. The first portion C2a, the second portion C2b, and the third portion C2c are interconnected. The third portion C2c is disposed between the fourth dummy gate structure DG4 and the gate structure G2.

In some embodiments, from a top view, an edge e7 of the first portion C2a is located outside the edge 3 of the active region OD. The second portion C2b is located outside the edge 4 of the active region OD. In some embodiments, from a top view, the edge e1 of the drain conductor MD2 is located outside the active region OD from a top view. The edge e5 of the gate structure G2 is located outside the active region OD from a top view.

In some embodiments, a connection element C1 is disposed on the active region OD and on both the first type doped region 41 and second type doped region 42. The connection element C1 comprises a first portion C1a, a second portion C1b, and a third portion C1c. The first portion C1a is disposed between the second dummy gate structure DG2 and the third dummy gate structure DG3. The first portion C1a, the second portion C1b, and the third portion C1c are integrated in one piece. In some embodiments, the first portion C1a, the second portion C1b, and the third portion C1c can be formed and connected by one or more operations. The first portion C1a and the third portion C1c can extend in the same direction (i.e., along the y-axis). The second portion C1b can extend in a direction (i.e., along the x-axis) perpendicular to that of the first portion C1a and the third portion C1c.

The connection element C1 can direct the current via the first portion C1a to the third portion C1c. The connection element C1 can direct the current from the second type doped region 42 to the first type doped region 41. The connection element C1 can bypass the path within the second type doped region 42 below the third dummy gate structure DG3 by directing the current. The connection element C1 can bypass the path within the first type doped region 41 below the fourth dummy gate structure DG4 by directing the current. The resistance value of the semiconductor device 15 can be reduced by directing the current through the connection element C1. The first portion C1a, the second portion C1b, and the third portion C1c are interconnected. The third portion C1c is disposed between the fourth dummy gate structure DG4 and the gate structure G2.

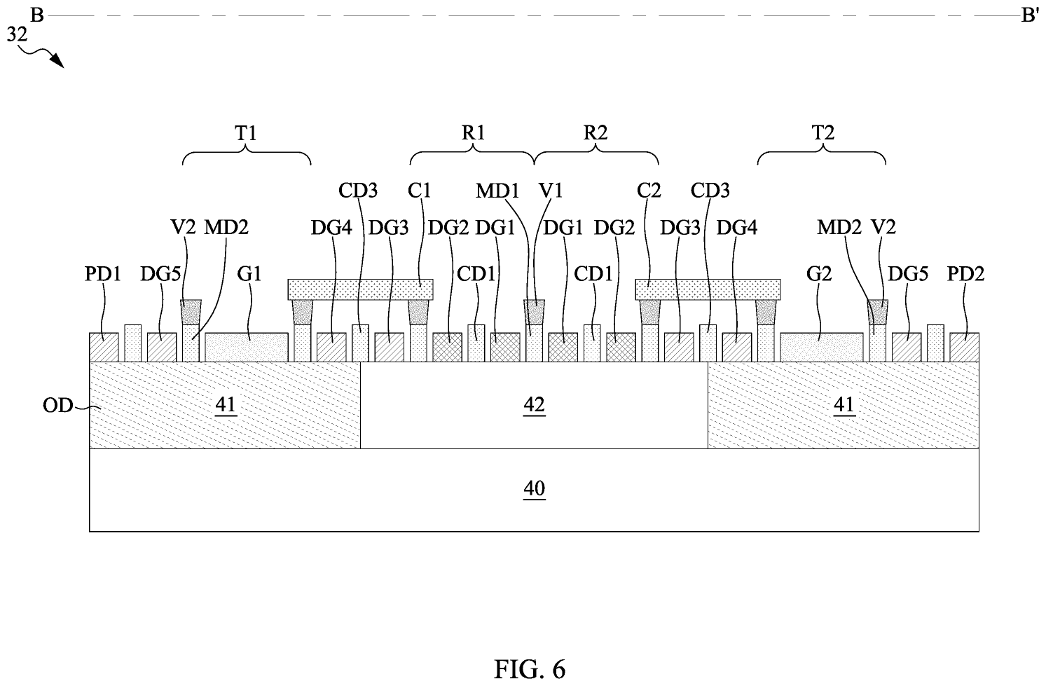

FIG. 6 is a cross section along the dashed line B-B′ of FIG. 5, in accordance with some embodiments, showing a semiconductor structure 32 including a substrate 40, an active region OD, gate structures G1 and G2, a source conductor MD1, drain conductors MD2, dummy gate structures DG1, DG2, DG3, DG4, and DG5, conductors CD1 and CD3, connection elements C1 and C2, and poly structures PD1 and PD2. Source/drain structure(s) or S/D structure(s) may refer to a source structure or a drain structure, individually or collectively dependent upon the context. The active region OD can also be referred to as oxide diffusion region OD. The poly structures PD1 and PD2 can be referred to as poly structures on OD edges, or simplified as “PODE.”

In some embodiments, the substrate 40 is a bulk substrate that includes silicon. Alternatively or additionally, the bulk substrate includes another elementary semiconductor, such as germanium; a compound semiconductor, such as silicon carbide, silicon phosphide, gallium arsenide, gallium phosphide, indium phosphide, indium arsenide, indium antimonide, zinc oxide, zinc selenide, zinc sulfide, zinc telluride, cadmium selenide, cadnium sulfide, and/or cadmium telluride; an alloy semiconductor, such as SiGe, SiPC, GaAsP, AlInAs, AlGaAs, GalnAs, GalnP, and/or GaInAsP; other group III-V materials; other group II-IV materials; or combinations thereof. Alternatively, the substrate 40 can be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates can be fabricated using separation by implantation of oxygen (SIMOX), wafer bonding, and/or other suitable methods.

The first type doped region 41 and second type doped region 42 are formed on the substrate 40. The first type doped region 41 is different from the second type doped region 42. In some embodiments, the first type doped region 41 is a p-type doped region and the second type doped region 42 is a n-type doped region. In some embodiments, the first type doped region 41 is a n-type doped region and the second type doped region 42 is a p-type doped region.

In some embodiments, when the transistor T1 is turned on or operated, the second type doped region 42 below the first dummy gate structure DG1 and the second dummy gate structure DG2 is configured to function as a resistor R1. The path within the second type doped region 42 through which the current passes corresponds to the resistor R1. The source conductor MD1 is disposed on the second type doped region 42. In some embodiments, when the transistor T2 is turned on or operated, the second type doped region 42 below the first dummy gate structure DG1 and the second dummy gate structure DG2 is configured to function as a resistor R2. The path within the second type doped region 42 through which the current passes corresponds to the resistor R2. The gate structure G1 is disposed between the source conductor MD1 and the drain conductor MD2. The gate structure G2 is disposed between the source conductor MD1 and the drain conductor MD2. The length of the source conductor MD1 is shorter than the length of the gate structure G1 from a top view. The length of the source conductor MD1 is shorter than the length of the gate structure G2 from a top view. The length of the drain conductor MD2 is shorter than the length of the gate structure G1 from a top view. The length of the drain conductor MD2 is shorter than the length of the gate structure G2 from a top view. The lengths of the source conductor MD1 and the drain conductor MD2 are the same. Therefore, the semiconductor structure 32 manufactured in accordance with the layout 30 can be referred to as a device with balanced source/drain conductors.

In some embodiments, the drain conductor MD2 is disposed over a single active region OD. In some embodiments, the drain conductor MD2 will not extend to another active region (not shown) adjacent to the active region OD depicted in FIG. 6. In some embodiments, a conductive via V1 is disposed on the source conductor MD1 and a conductive via V2 is disposed on the drain conductor MD2.

In some embodiments, the source conductor MD1, the gate structures G1 and G2, and the drain conductors MD2 can constitute a transistor T1/T2 having resistor regions electrically connected to the source of the transistor T1/T2. In some embodiments, the source conductor MD1 can range from 0.1 times to 0.9 times that of the drain conductor MD2 from a top view. In some embodiments, the source conductor MD1 can range from 0.1 times to 0.9 times that of the gate structure G1 from a top view.

The poly structures PD1 and PD2 are useful in process control during manufacturing. The dummy gate structures DG1 and DG2 are optional (i.e., not mandatory in the semiconductor structure 32) and can be useful in reducing layout dependence effects. The total number of the dummy gate structures can be increased or decreased depending on the user requirements.

In some embodiments, when the transistor T1 is turned on or operated, the current from the source conductor MD1 may pass through the path below the first dummy gate structure DG1 and the second dummy gate structure DG2, and pass through the connection element C1. Then, the current passes through the path/channel below the gate structure G1 and passes through the drain conductor MD2 of the transistor T1. The source conductor MD1, drain conductor MD2, dummy gate structures DG1 to DG5, gate structures G1 and G2, and poly structures PD1 and PD2 are formed by any suitable process including various deposition, photolithography, and/or etching processes. An exemplary photolithography process includes forming a photoresist layer (resist) overlying substrate 40, exposing the resist to a pattern, performing a post-exposure bake process, and developing the resist to form a masking element including the resist.

In some embodiments, a third dummy gate structure DG3 is disposed on the second type doped region 42. In some embodiments, a fourth dummy gate structure DG4 is disposed on the first type doped region 41 different from the second type doped region 42. In some embodiments, a connection element C2 is disposed on the active region OD and on both the first type doped region 41 and second type doped region 42. The connection element C2 comprises a first portion C2a, a second portion C2b, and a third portion C2c. The first portion C2a is disposed between the second dummy gate structure DG2 and the third dummy gate structure DG3. The first portion C2a, the second portion C2b, and the third portion C2c are integrated in one piece. The connection element C2 can direct the current via the first portion C2a to the third portion C2c. The connection element C2 can direct the current from the second type doped region 42 to the first type doped region 41. The connection element C2 can bypass the path within the second type doped region 42 below the third dummy gate structure DG3 by directing the current. The connection element C2 can bypass the path within the first type doped region 41 below the fourth dummy gate structure DG4 by directing the current. The resistance value of the semiconductor device 15 can be reduced by directing the current through the connection element C2. The first portion C2a, the second portion C2b, and the third portion C2c are interconnected. The third portion C2c is disposed between the fourth dummy gate structure DG4 and the gate structure G2.

In some embodiments, a fourth dummy gate structure DG4 is disposed on the first type doped region 41 of the transistor T1 and on the second type doped region 42 of the resistor R1. A fourth dummy gate structure DG4 is disposed on the first type doped region 41 of the transistor T2 and on the second type doped region 42 of the resistor R2. In some embodiments, a connection element C1 is disposed on the active region OD and on both the first type doped region 41 and second type doped region 42. The connection element C1 comprises a first portion C1a, a second portion C1b, and a third portion C1c. The first portion C1a is disposed between the second dummy gate structure DG2 and the third dummy gate structure DG3. The first portion C1a, the second portion C1b, and the third portion C1c are integrated in one piece. The connection element C1 can direct the current via the first portion C1a to the third portion C1c. The connection element C1 can direct the current from the second type doped region 42 to the first type doped region 41. The connection element C1 can bypass the path within the second type doped region 42 below the third dummy gate structure DG3 by directing the current. The connection element C1 can bypass the path within the first type doped region 41 below the fourth dummy gate structure DG4 by directing the current. The resistance value of the semiconductor device 15 can be reduced by directing the current through the connection element C1. The first portion C1a, the second portion C1b, and the third portion C1c are interconnected. The third portion C1c is disposed between the fourth dummy gate structure DG4 and the gate structure G2.

The source/drain conductor MD1/MD2 are disposed on the epitaxial contacts 44. The epitaxial contacts 44 are epitaxially grown in the S/D region of the transistors T1/T2. In some embodiments, the source conductor MD1 includes a via and a conductive contact. In some embodiments, the drain conductor MD2 includes a via and a conductive contact. The active region OD can also be referred to as oxide diffusion region OD. The poly structures PD1 and PD2 can be referred to as poly structures on OD edges, or simplified as “PODE.”

In some embodiments, the gate structures G1 and G2 can be electrically connected to the same voltage reference. In some embodiments, the gate structures G1 and G2 can be electrically connected to different voltage references. The gate structures G1 and G2 can be electrically connected through upper-layered interconnections (not shown). The drain conductors MD2 can be electrically connected to the same voltage reference. The drain conductors MD2 can be electrically connected through upper-layered interconnections (not shown). The source conductor MD1 can be electrically connected through upper-layered interconnections (not shown). With the multi-finger structure shown in FIG. 6, the resistance of the equivalent resistor R1 and R2 constituted by the regions below the dummy gate structures DG1 and DG2 can be adjusted according to need. In some embodiments, the drain conductors MD2 are disposed over a single active region OD. In some embodiments, the drain conductors MD2 will not extend to another active region (not shown) adjacent to the active region OD depicted in FIG. 6. In some embodiments, the numbers of the dummy gate structures can be adjusted in accordance with actual design needs. In some embodiments, the number of the dummy gate structures can range from 1 to 30. In some embodiments, the dimensions of the dummy gate structures can range from 3 nm to 2 μm (micrometer).

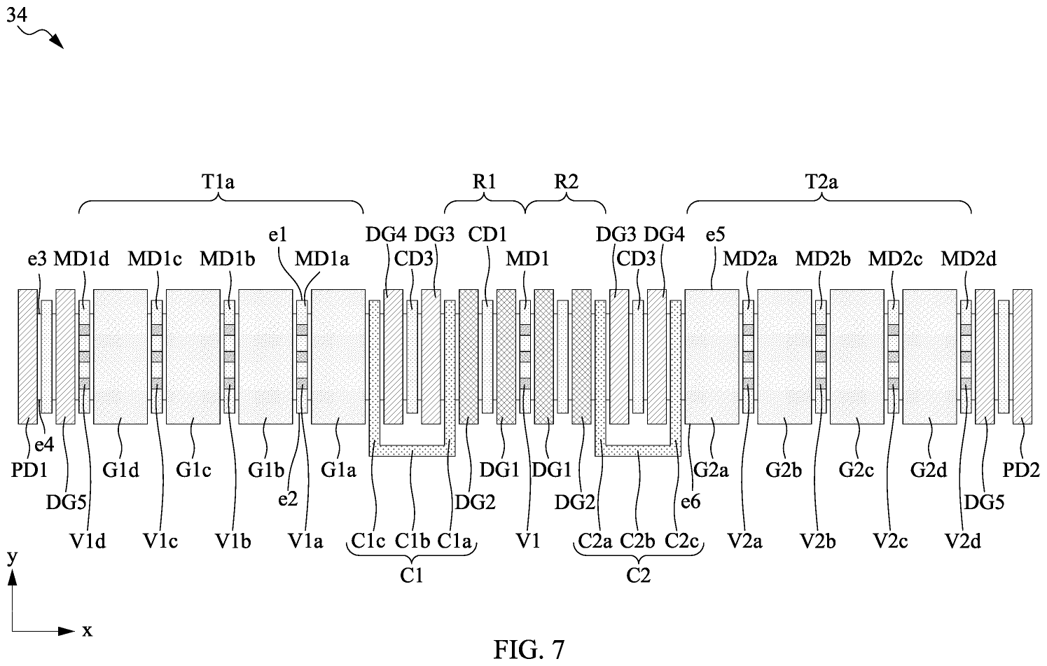

FIG. 7 is a layout of a semiconductor device including transistors and two embedded resistors, in accordance with some embodiments. The layout 34 shown in FIG. 7 pertains to a semiconductor device including eight transistors and two resistors. The layout 34 can correspond to a top view perspective of a semiconductor device including eight transistors and two resistors. The layout 34 includes an active region OD, gate structures G1a to G1d, gate structures G2a to G2d, a source conductor MD1, conductors MD2a to MD2d, dummy gate structures DG1. DG2, DG3, DG3, DG4, and DG5, and poly structures PD1 and PD2. The active region OD can also be referred to as oxide diffusion region OD. The poly structures PD1 and PD2 can be referred to as poly structures on OD edges, or simply as “PODE.”

A transistor structure Tla includes gate structures G1a to G1d. A transistor structure T2a includes gate structures G2a to G2d. The gate structure G1a is disposed between the source conductor MD1 and the conductor MD1a. The conductor MD1a may function as a drain conductor of the gate structure G1a. The gate structure G1b is disposed between the source conductor MD1 and the conductor MD1b. In some embodiments, the conductor MD1b may function as a drain conductor of the gate structure G1b and the conductor MD1a may function as the source conductor of the gate structure G1b. The length of the source conductor MD1a is shorter than the length of the gate structure G1a from a top view. The length of the source conductor MD1a is shorter than the length of the gate structure G2a from a top view. The length of the drain conductor MD2a is shorter than the length of the gate structure G1a from a top view. The length of the drain conductor MD2a is shorter than the length of the gate structure G2a from a top view. Since the lengths of the source conductor MD1a and the lengths of the drain conductors MD2a to MD2d are the same, the semiconductor device manufactured in accordance with the layout 34 can be referred to as a device with balanced source/drain conductors.

The transistor structure T2a comprises the source conductor MD1, gate structure G2a, conductor MD2a, gate structure G2b, conductor MD2b, gate structure G2c, conductor MD2c, gate structure G2d, and conductor MD2d disposed on the active region OD. The dummy gate structure DG1 is disposed between the gate structure G2a and the source conductor MD1. The transistor structure T2a comprises a first type doped region 41 and a second type doped region 42 adjacent to the first type doped region 41. The first type doped region 41 is disposed below the gate structure G2a, the gate structure G2b, the conductor MD2c, and the gate structure G2d. The second type doped region. 42 of the active region OD is adjacent to the first type doped region, and the first type doped region is different from the second type doped region. The dummy gate structure DG1 is disposed on the second type doped region 42. The dummy gate structure DG2 is disposed on the second type doped region 42. The dummy gate structure DG2 is disposed between the dummy gate structure DG1 and the source conductor MD1. The dummy gate structure DG3 is disposed on the second type doped region 42 and the dummy gate structure DG4 is disposed on the first type doped region 41. The first portion C2a, the second portion C2b, and the third portion C2c are integrated in one piece. The third portion C2c is disposed between the dummy gate structure DG4 and the first gate structure G2a.

The drain conductor MD1a includes edges e1 and e2, the active region OD includes edges e3 and e4, and the gate conductor G2a includes edges e5 and e6. The edges e3 and e4 of the active region OD can also be referred to as boundaries e3 and e4. The edge e1 of the drain conductor MD2a is misaligned with the edge e3 of the active region OD, and edge e2 of the drain conductor MD2a is misaligned with the edge e4 of the active region OD. The edges e3 and e4 of the active region OD can be located between edges e1 and e2 of the drain conductor MD2a. The edges e3 and e4 of the active region OD can be located between edges e5 and e6 of the gate conductor G2a.

The edge e5 of the gate conductor G2a is misaligned with the edge e3 of the active region OD, and edge e6 of the gate conductor G2a is misaligned with the edge e4 of the active region OD. The edges e1 and e2 of the drain conductor MD2a are both outside the area (e.g., defined by edges e3 and e4) of the active region OD. The edge e1 of the drain conductor MD2a is misaligned with the edge e5 of the gate conductor G2a, and edge e2 of the drain conductor MD2a is misaligned with the edge e6 of the gate conductor G2a.

In some embodiments, the drain conductors MD2a to MD2d are disposed over a single active region OD. In some embodiments, the drain conductor MD2a to MD2d will not extend to another active region (not shown) adjacent to the active region OD depicted in FIG. 7. In some embodiments, the drain conductor MD1a to MD1d will not extend to another active region (not shown) adjacent to the active region OD depicted in FIG. 7.

The source conductor MD1, the gate structures G1a to Gd, and the conductors MD1a to MD1d can constitute four transistors G1a to G1d having resistor regions electrically connected to the source of the transistor G1a. In some embodiments, the length of the source conductor MD1a can range from 0.1 times to 0.9 times that of the drain conductor MD2a from a top view. In some embodiments, the length of the source conductor MD1a can range from 0.1 times to 0.9 times that of the gate structure G1a from a top view. In some embodiments, a conductive via V1 is disposed on the source conductor MD1. In some embodiments, a conductive via V1a is disposed on the conductor MD1a, a conductive via V1b is disposed on the conductor MD1b, a conductive via V1c is disposed on the conductor MD1c, and a conductive via V1d is disposed on the conductor MD1d. In some embodiments, a conductive via V2a is disposed on the conductor MD2a, a conductive via V2b is disposed on the conductor MD2b, a conductive via V2c is disposed on the conductor MD2c, and a conductive via V2d is disposed on the conductor MD2d.

In some embodiments, the source conductor MD1a (i.e., along the y-axis) can range from 0.01 μm to 5 μm. In some embodiments, the length of the drain conductor MD2a (i.e., along the y-axis) can range from 0.01 μm to 5 μm. In some embodiments, the width of the gate structure G1 (i.e., along the x-axis) can range from 0.001 μm to 10 μm. The poly structures PD1 and PD2 can be useful in process control during manufacturing. The dummy gate structures DG1 and DG2 are optional (i.e., not mandatory in the layout 30) and can be useful in reducing layout dependence effects. The number of the dummy gate structures can be increased or decreased depending on the user requirements.

In some embodiments, a third dummy gate structure DG3 is disposed on the second type doped region 42. In some embodiments, a fourth dummy gate structure DG4 is disposed on the first type doped region 41. In some embodiments, a connection element C2 is disposed on the active region OD. The connection element C2 comprises a first portion C2a, a second portion C2b, and a third portion C2c. The first portion C2a is disposed between the second dummy gate structure DG2 and the third dummy gate structure DG3. The first portion C2a, the second portion C2b, and the third portion C2c are integrated in one piece. The connection element C2 can direct the current via the first portion C2a to the third portion C2c. The connection element C2 can bypass the path within the second type doped region 42 below the third dummy gate structure DG3 by directing the current. The connection element C2 can bypass the path within the first type doped region 41 below the fourth dummy gate structure DG4 by directing the current. The resistance value of the semiconductor device 15 can be reduced by directing the current through the connection element C2. The first portion C2a, the second portion C2b, and the third portion C2c are interconnected. The third portion C2c is disposed between the fourth dummy gate structure DG4 and the gate structure G2a.

In some embodiments, from a top view, an edge e7 of the first portion C2a is located outside the edge 3 of the active region OD. The second portion C2b is located outside the edge 4 of the active region OD. In some embodiments, from a top view, the edge e1 of the drain conductor MD2a is located outside the active region OD from a top view. The edge e5 of the gate structure G2a is located outside the active region OD from a top view.

In some embodiments, a connection element C1 is disposed on the active region OD and on both the first type doped region 41 and second type doped region 42. The connection element C1 comprises a first portion C1a, a second portion C1b, and a third portion C1c. The first portion C1a is disposed between the second dummy gate structure DG2 and the third dummy gate structure DG3. The first portion C1a, the second portion C1b, and the third portion C1c are integrated in one piece. The connection element C1 can direct the current via the first portion C1a to the third portion C1c. The connection element C1 can direct the current from the second type doped region 42 to the first type doped region 41. The connection element C1 can bypass the path within the second type doped region 42 below the third dummy gate structure DG3 by directing the current. The connection element C1 can bypass the path within the first type doped region 41 below the fourth dummy gate structure DG4 by directing the current. The resistance value of the semiconductor device 15 can be reduced by directing the current through the connection element C1. The first portion C1a, the second portion C1b, and the third portion C1c are interconnected. The third portion C1c is disposed between the fourth dummy gate structure DG4 and the gate structure G2a.

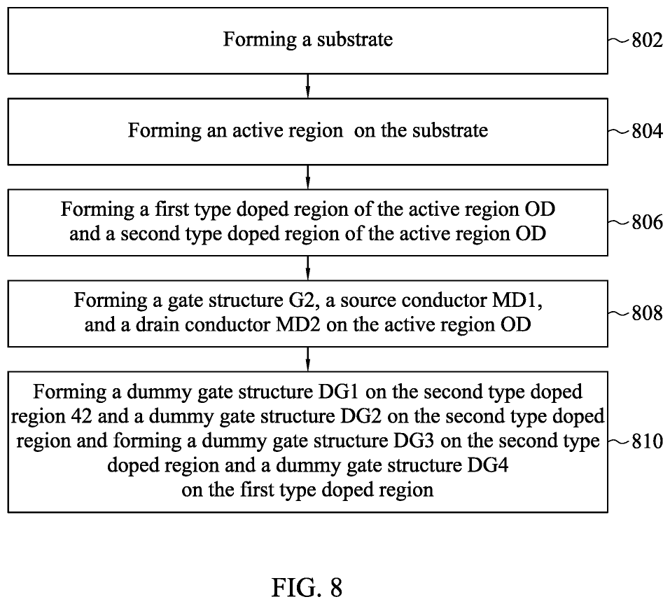

FIG. 8 is a flowchart of a method 800 of manufacturing a semiconductor device, in accordance with some embodiments. The method 800 is operable to form a current mirror circuit (e.g., the 20 current mirror circuit shown in FIG. 2) that includes a transistor having an embedded resistor, as discussed in accordance with the layouts 30 and 34 of FIGS. 5 and 7.

In some embodiments, the operations of method 800 are performed in the order depicted in FIG. 8. In some embodiments, the operations of method 8 are performed in an order other than that depicted in FIG. 8 and/or two or more operations of method 800 are performed simultaneously. In some embodiments, one or more additional operations are performed before, during, and/or after the operations of method 800.

In operation 802, a substrate is formed. In operation 804, an active region is formed on the substrate. In some embodiments, the active region may correspond to the active region OD in accordance with some embodiments. In operation 806, a first type doped region 41 of the active region OD is formed and a second type doped region 42 of the active region OD is formed adjacent to the first type doped region. In some embodiments, the first type doped region is different from the second type doped region. In operation 808, a gate structure G2, a source conductor MD1, and a drain conductor MD2 are formed on the active region OD. In some embodiments, the second type doped region 42 is is configured to function as a resistor 48.

In operation 810, a dummy gate structure DG1 is formed on the second type doped region 42 and a dummy gate structure DG2 is formed on the second type doped region 42, and a dummy gate structure DG3 is formed on the second type doped region 42 and a dummy gate structure DG4 is formed on the first type doped region 41.

According to some embodiments, a semiconductor device is provided. The semiconductor device includes a substrate, an active region on the substrate, and a gate structure, a source conductor, and a drain conductor disposed on the active region. The semiconductor device further comprises a first type doped region of the active region below the gate structure and a second type doped region of the active region adjacent to the first type doped region, and the first type doped region is different from the second type doped region. The second type doped region is configured to function as a resistor.

According to some embodiments, a semiconductor device is provided. The semiconductor device includes a substrate, an active region on the substrate, a source conductor, a first gate structure, a first conductor, a second gate structure, a second conductor, a third gate structure, a third conductor, a fourth gate structure, a fourth conductor disposed on the active region, and a first dummy gate structure disposed between the first gate structure and the source conductor, a first type doped region of the active region, and a second type doped region of the active region adjacent to the first type doped region. The first type doped region is disposed below the the first gate structure, the second gate structure, the third conductor, and the fourth gate structure. The second type doped region of the active region is adjacent to the first type doped region, and the first type doped region is different from the second type doped region.

According to some embodiments, a method of manufacturing a semiconductor device comprises forming a substrate, forming an active region on the substrate, forming a first type doped region of the active region below the gate structure and a second type doped region of the active region adjacent to the first type doped region, wherein the first type doped region is different from the second type doped region, and forming a gate structure, a source conductor, and a drain conductor on the active region, wherein the second type doped region is configured to function as a resistor.

The methods and features of the present disclosure have been sufficiently described in the examples and descriptions provided. It should be understood that any modifications or changes without departing from the spirit of the present disclosure are intended to be covered in the protection scope of the present disclosure.

Moreover, the scope of the present application in not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope processes, machines, manufacture, compositions of matter, means, methods, or steps. In addition, each claim constitutes a separate embodiment, and the combination of various claims and embodiments are within the scope of the present disclosure.

What is claimed is:

1. A semiconductor device, comprising:
a substrate;
an active region on the substrate;
a gate structure, a source conductor, and a drain conductor disposed on the active region, wherein:
the semiconductor device further comprises a first type doped region of the active region below the gate structure and a second type doped region of the active region adjacent to the first type doped region, and the first type doped region is different from the second type doped region; and
the second type doped region is configured to function as a resistor.

2. The semiconductor device of claim 1, further comprising a first dummy gate structure disposed on the second type doped region.

3. The semiconductor device of claim 2, further comprising a second dummy gate structure disposed on the second type doped region, wherein the second dummy gate structure is disposed between the first dummy gate structure and the source conductor.

4. The semiconductor device of claim 2, further comprising a first epitaxial contact disposed between the first dummy gate structure and the gate structure.

5. The semiconductor device of claim 3, wherein the epitaxial contact is disposed adjacent to an interface between a boundary of the first type doped region and a boundary of the second type doped region.

6. The semiconductor device of claim 1, further comprising a second epitaxial contact disposed between the first dummy gate structure and the second dummy gate structure.

7. The semiconductor device of claim 3, further comprising a third dummy gate structure disposed on the second type doped region and a fourth dummy gate structure disposed on the first type doped region.

8. The semiconductor device of claim 7, further comprising a connection element disposed on the active region, wherein the connection element comprises a first portion, a second portion, and a third portion, wherein the first portion is disposed between the second dummy gate structure and the third dummy gate structure.

9. The semiconductor device of claim 8, wherein the first portion, the second portion, and the third portion are interconnected, and wherein the third portion is disposed between the fourth dummy gate structure and the gate structure.

10. The semiconductor device of claim 9, wherein, from a top view, an edge of the first portion is located outside the active region.

11. The semiconductor device of claim 1, wherein, from a top view, an edge of the drain conductor is located outside the active region, and an edge of the gate structure is located outside the active region.

12. A semiconductor device, comprising:
a substrate;
an active region on the substrate;
a source conductor, a first gate structure, a first conductor, a second gate structure, a second conductor, a third gate structure, a third conductor, a fourth gate structure, and a fourth conductor disposed on the active region;
a first dummy gate structure disposed between the first gate structure and the source conductor;
wherein:
the semiconductor device further comprises a first type doped region of the active region and a second type doped region of the active region adjacent to the first type doped region,
the first type doped region is disposed below the the first gate structure, the second gate structure, the third conductor, and the fourth gate structure, and the second type doped region of the active region is adjacent to the first type doped region, and the first type doped region is different from the second type doped region.

13. The semiconductor device of claim 12, wherein the first dummy gate structure is disposed on the second type doped region.

14. The semiconductor device of claim 13, further comprising a second dummy gate structure disposed on the second type doped region, wherein the second dummy gate structure is disposed between the first dummy gate structure and the source conductor.

15. The semiconductor device of claim 14, further comprising a third dummy gate structure disposed on the second type doped region and a fourth dummy gate structure disposed on the first type doped region.

16. The semiconductor device of claim 15, further comprising a connection element disposed on the active region, wherein the connection element comprises a first portion, a second portion, and a third portion, wherein the first portion is disposed between the second dummy gate structure and the third dummy gate structure.

17. The semiconductor device of claim 16, wherein the first portion, the second portion, and the third portion are interconnected, wherein the third portion is disposed between the fourth dummy gate structure and the first gate structure.

18. A method of manufacturing a semiconductor device, comprising:
forming a substrate;
forming an active region on the substrate;
forming a first type doped region of the active region below the gate structure and a second type doped region of the active region adjacent to the first type doped region, wherein the first type doped region is different from the second type doped region; and
forming a gate structure, a source conductor, and a drain conductor on the active region;
wherein the second type doped region is configured to function as a resistor.

19. The method of claim 18, further comprising forming a first dummy gate structure on the second type doped region and a second dummy gate structure on the second type doped region, wherein the second dummy gate structure is disposed between the first dummy gate structure and the source conductor.

20. The method of claim 19, further comprising forming a third dummy gate structure on the second type doped region and a fourth dummy gate structure on the first type doped region.
